(19) United States
(12) Patent Application Publication
(10) Pub. No.: US 2018/0006189 A1
(43) Pub. Date: Jan. 4, 2018

(54) EPITAXIAL STRUCTURE WITH TUNNEL JUNCTION, P-SIDE UP PROCESSING INTERMEDIATE STRUCTURE AND METHOD OF MANUFACTURING THE SAME

(71) Applicant: EPILEDS TECHNOLOGIES, INC., TAINAN CITY (TW)

(72) Inventors: Tzu-Wen Wang, Kaohsiung City (TW); Wei-Yu Tseng, Kaohsiung City (TW)

(73) Assignee: EPILEDS TECHNOLOGIES, INC.

(21) Appl. No.: 15/432,069

(22) Filed: Feb. 14, 2017

(30) Foreign Application Priority Data
Jun. 29, 2016 (TW) 105120545

(51) Int. Cl. H01L 33/14; H01L 33/06; H01L 33/00; H01L 33/30; H01L 33/40

(52) U.S. Cl. CPC H01L 33/14; H01L 33/30; H01L 33/40; H01L 33/0062; H01L 33/06; H01L 33/0079; H01L 2933/0016

(57) ABSTRACT

An epitaxial structure with a tunnel junction, a p-side up processing intermediate structure and a manufacturing method thereof are provided. The epitaxial structure includes: a substrate, a first n-type semiconductor layer, a tunnel junction layer, a p-type semiconductor layer, a multiple quantum well layer and a second n-type semiconductor layer, wherein the first n-type and p-type semiconductor layers and the tunnel junction layer together form a p-type semiconductor structure. The manufacturing method of the p-side up processing intermediate structure includes disposing a permanent substrate on the second n-type semiconductor layer to form a laminated structure, flipping the laminated structure upside down and removing the substrate of the epitaxial structure, thereby resulting in the p-type semiconductor structure being disposed facing up.

### CROSS-REFERENCE TO RELATED APPLICATION

This application claims priority from Taiwan Patent Application No. 105120545 filed on Jun. 29, 2016 at the Taiwan Intellectual Property Office, the content of which is hereby incorporated by reference in its entirety for all purposes.

### BACKGROUND OF THE INVENTION

### 1. Field of the Invention

The present invention relates to a semiconductor epitaxial structure, a processing intermediate structure, and the method of manufacturing the is same. Specifically, it relates to an epitaxial structure having a tunnel junction layer, an intermediate structure having its p-type semiconductor layer facing upward, and the method of manufacturing the same.

### 2. Description of the Related Art

A die of a light-emitting diode includes an n-type semiconductor layer and a p-type semiconductor layer. In order to produce a light-emitting diode with the p-type semiconductor layer facing upward, multiple flipping steps are applied in the conventional epitaxial process. FIG. 1 shows a conventional manufacturing process flow for a die with the p-type semiconductor layer facing upward. As shown in FIG. 1, an n-type semiconductor layer 101, a multiple quantum well (MQW) layer 102, and a p-type semiconductor layer 103 are sequentially deposited on a gallium arsenide substrate 100. Then, a temporary substrate 104 is bonded onto the p-type semiconductor layer 103 to form the first stack structure 10. The first stack structure 10 is then flipped to remove the uppermost substrate 100 so as to expose the n-type semiconductor layer 101. Then, a permanent substrate 105 is bonded onto the exposed uppermost n-type semiconductor layer 101 to form the second stack structure 15. The second stack structure 15 is flipped again to remove the temporary substrate 104 so as to expose the p-type semiconductor layer 103 and finally form the final structure of the die with its uppermost p-type semiconductor layer facing upward.

Although the manufacturing process flow produces the required intermediate structure with the upward-facing p-type semiconductor layer, the two flips in the manufacturing process are time consuming and there is material waste due to use of the temporary substrate, and both of these factors increase the production cost.

Also, in the subsequent interface formation process between the semiconductor and the metal in, for instance, the formation of an ohmic contact; the intermediate structure of the upward-facing p-type semiconductor layer as produced by the aforementioned manufacturing process flow requires a bonding temperature higher than 500° C., which is a higher bonding temperature than the bonding temperature required for the n-type semiconductor layer, which is not favorable for a subsequent process.

### SUMMARY OF THE INVENTION

To solve the aforementioned technical problems, the purpose of the present invention is to offer a processing intermediate structure, which provides for a better condition for the subsequent process of forming an interface between the semiconductor and metal, and also to provide for a simplified semiconductor manufacturing process flow.

In order to achieve the said purpose, the present invention provides an epitaxial structure having a tunnel junction layer and includes a first substrate, a first n-type semiconductor layer disposed on the first substrate, the tunnel junction layer disposed on the first n-type semiconductor layer, a p-type semiconductor layer disposed on the tunnel junction layer, and a second n-type semiconductor layer disposed on the p-type semiconductor layer, wherein the first n-type semiconductor layer, the tunnel junction layer, and the p-type semiconductor layer jointly form a p-type semiconductor structure.

Preferably, the epitaxial structure further includes a multiple quantum well layer, which may be disposed between the p-type semiconductor structure and the second n-type semiconductor layer.

Preferably, the first n-type semiconductor layer, the p-type semiconductor layer, and the second n-type semiconductor layer may include gallium arsenide, aluminum gallium arsenide, gallium nitride, or gallium phosphide.

Preferably, the tunnel junction layer may include both a heavily doped n-type layer and a heavily doped p-type layer, and the heavily doped n-type and p-type layers may include AlGaInAs:Te/C or AlGaAs:Te/C.

The present invention provides a method of manufacturing a p-side up processing intermediate structure, which includes the following steps: providing a first substrate; forming a first n-type semiconductor layer on the first substrate; forming a p-type semiconductor layer on the first n-type semiconductor layer; forming a tunnel junction layer between the first n-type semiconductor layer and the p-type semiconductor layer so that the first n-type semiconductor layer, the p-type semiconductor layer, and the tunnel junction layer jointly form a p-type semiconductor structure; forming a second n-type semiconductor layer on the p-type semiconductor structure; bonding a second substrate onto the second n-type semiconductor layer to form a stack structure; then turning the stack structure upside down and removing the first substrate.

Preferably, the method may further include a step of forming a multiple quantum well layer between the p-type semiconductor structure and the second n-type semiconductor layer.

Preferably, the method may further include a step of forming a metal layer between the first substrate and the first n-type semiconductor layer so as to form an ohmic contact.

Preferably, the method may further include forming another metal layer between the second n-type semiconductor layer and the second substrate so as to form an ohmic contact.

Preferably, the first n-type semiconductor layer, the p-type semiconductor layer, and the second n-type semiconductor layer may include gallium arsenide, aluminum gallium arsenide, gallium nitride, or gallium phosphide.

Preferably, the tunnel junction layer may include both a heavily doped n-type layer and a heavily doped p-type layer, and the heavily doped n-type and p-type layers may include AlGaInAs:Te/C or AlGaAs:Te/C.

A p-side up processing intermediate structure from bottom to top sequentially includes a second substrate, a second n-type semiconductor layer disposed on the second substrate, and a p-type semiconductor structure disposed on the second n-type semiconductor layer. Wherein, the p-type semiconductor structure includes a p-type semiconductor layer disposed on the second n-type semiconductor layer, a first n-type semiconductor layer disposed on the p-type semiconductor layer, and a tunnel junction layer disposed between the p-type semiconductor layer and the first n-type semiconductor layer.

Preferably, a multiple quantum well layer may be disposed between the second n-type semiconductor layer and the p-type semiconductor structure.

Preferably, the first n-type semiconductor layer, the p-type semiconductor layer, and the second n-type semiconductor layer may include gallium arsenide, aluminum gallium arsenide, gallium nitride, or gallium phosphide.

Preferably, a metal layer may be disposed between the second substrate and the second n-type semiconductor layer.

Preferably, another metal layer may be disposed on the first n-type semiconductor layer.

Preferably, the tunnel junction layer may include both a heavily doped n-type layer and a heavily doped p-type layer, and the heavily doped n-type and p-type layers may include AlGaInAs:Te/C or AlGaAs:Te/C.

As previously mentioned, the present invention provides the epitaxial structure having the tunnel junction layer, the p-side up processing intermediate structure, and the method of manufacturing the same, wherein the tunnel junction layer disposed between the p-type semiconductor layer and the n-type semiconductor layer provides one or more of following advantages:

(1) Within the processing intermediate structure of the present invention, the combination of the p-type semiconductor layer, the tunnel junction layer and the n-type semiconductor layer shows the properties of a p-type semiconductor, that is overall the trilayer combination is p-type relative to the other n-type semiconductor layer, and therefore the three layers together form the p-type semiconductor structure.

(2) The manufacturing process of the processing intermediate structure of the present invention is greatly simplified as only one flipping process step is needed to form the desired p-side up semiconductor structure.

(3) The processing intermediate structure of the present invention includes two n-type semiconductor layers, onto which ohmic contacts can be subsequently formed, thereby avoiding the processing difficulty of forming an ohmic contact on a p-type semiconductor layer.

### BRIEF DESCRIPTION OF THE DRAWINGS

FIG. 1 is a process diagram showing a conventional manufacturing process flow for a die with the p-type semiconductor layer facing upward.

FIG. 2 is a flowchart showing a manufacturing process of the processing intermediate structure with the p-type semiconductor structure facing upward, that is the p-side up processing intermediate structure, according to an embodiment of the present invention.

FIGS. 3 and 4 are schematic diagrams showing the processing intermediate structure in stages before and after flipping respectively of the manufacturing process of the p-side up processing intermediate structure according to the first embodiment of the present invention.

FIG. 5 is a schematic diagram showing a p-side up processing intermediate structure according to the second embodiment of the present invention.

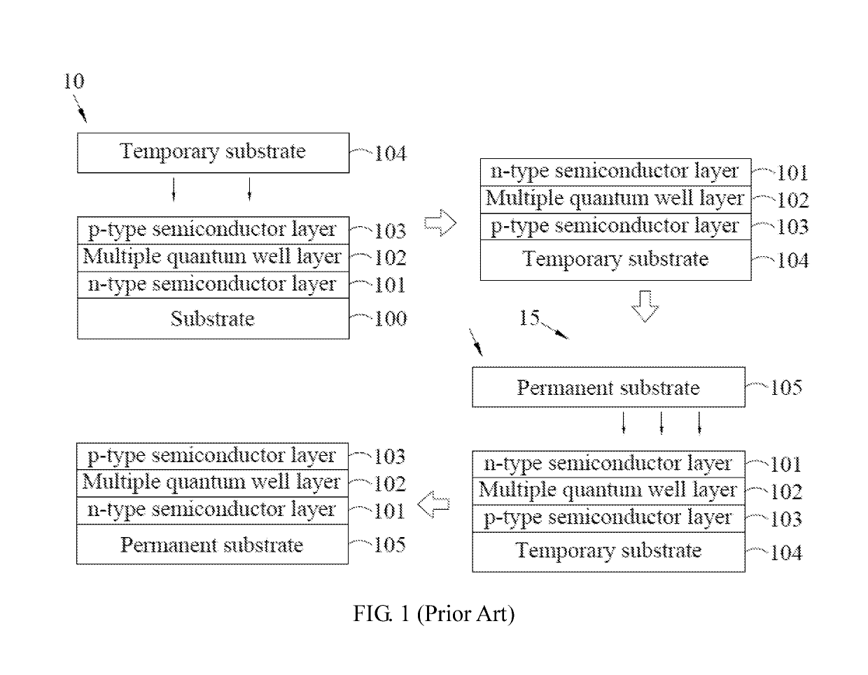

### DESCRIPTION OF THE PREFERRED EMBODIMENTS

The technical characteristics, implementation and advantages of the present invention are further explained in the following detailed description of preferred embodiments thereof, which refer to the accompanying drawings. It is, however, intended that the embodiments and figures disclosed herein are for the purpose of illustration only and shall not be interpreted in any way to limit the scope, applicability or configuration of the present invention.

The following one or more embodiments of the present invention disclose an epitaxial structure having a tunnel junction layer, a p-side up processing intermediate structure, and a method of manufacturing the processing intermediate structure. As disclosed in the following embodiments of an epitaxial structure having a p-type semiconductor structure, the p-side up processing intermediate structure, and the method of manufacturing the same, only a low processing temperature is required to form an ohmic contact for the processing intermediate structure, which is advantageous for the subsequent process. In addition, the following embodiments disclose the epitaxial structure having the tunnel junction layer, and that the use thereof can simplify the manufacturing process flow of the p-side up processing intermediate structure, and therefore also reduce the processing time and cost.

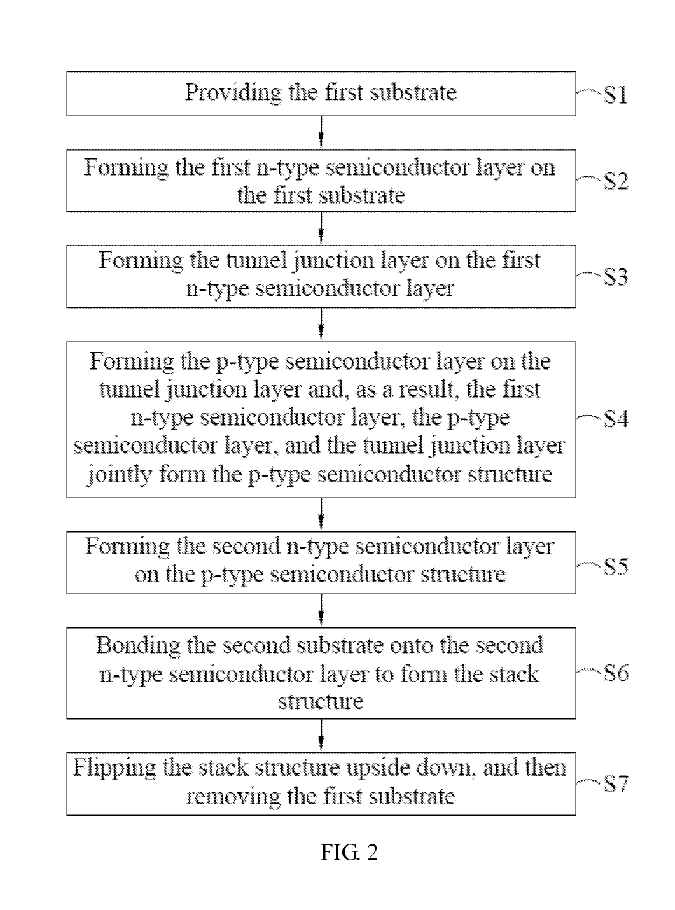

The following refers to FIG. 2, which is a flowchart showing the manufacturing process, which produces the epitaxial structure having the tunnel junction layer, and then following final steps the epitaxial structure becomes the p-side up processing intermediate structure. As shown in FIG. 2, the manufacturing method includes: a step S1 of providing the first substrate; a step S2 of forming the first n-type semiconductor layer on the first substrate; a step S3 of forming the tunnel junction layer on the first n-type semiconductor layer; a step S4 of forming the p-type semiconductor layer on the tunnel junction layer and, as a result, the first n-type semiconductor layer, the p-type semiconductor layer, and the tunnel junction layer jointly form the p-type semiconductor structure; a step S5 of forming the second n-type semiconductor layer on the p-type semiconductor structure; a step S6 of bonding the second substrate on the second n-type semiconductor layer to form the stack structure; and a step S7 of flipping the stack structure upside down and removing the first substrate. The epitaxial structure is formed in the steps S1 to S5, and then the process of manufacturing the intermediate structure is completed after flipping the stack structure upside down and removing the first substrate in S7.

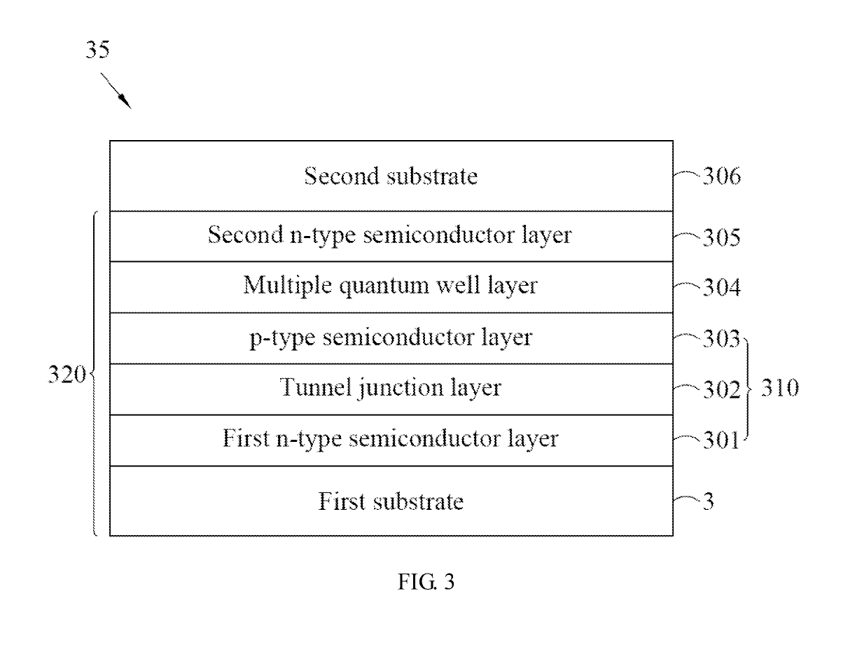

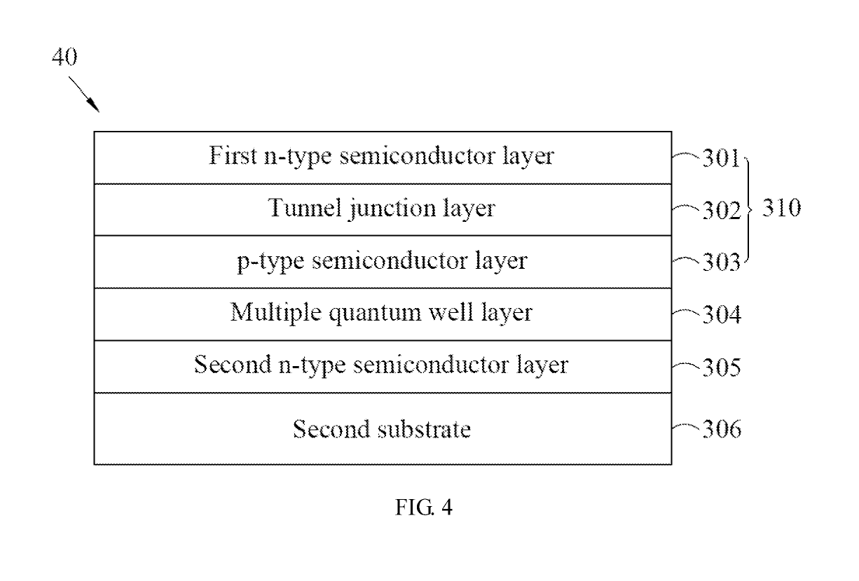

Based on the aforementioned process flow of the processing intermediate structure, the present invention provides a first embodiment of the manufacturing method of the processing intermediate structure, which is further illustrated with FIGS. 3 and 4, which show the processing intermediate structure in stages before and after flipping respectively of the manufacturing process of the p-side up processing intermediate structure according to the first embodiment of the present invention. Referring to FIG. 3, firstly, the first substrate 3 is provided. The first substrate 3 may be gallium arsenide (GaAs), aluminum gallium arsenide (AlGaAs), gallium nitride (GaN), or gallium phosphide (GaP), but the present invention is not limited to these. Preferably, the first substrate is formed of gallium arsenide (GaAs). Secondly, the first n-type semiconductor layer 301 is formed on the first substrate 3. The first n-type semiconductor layer 301 is n-type gallium arsenide, and preferably doped with silicon (Si) or Tellurium (Te). Thirdly, the tunnel junction layer 302 is disposed on the first n-type semiconductor layer 301 and the p-type semiconductor layer 303 is sequentially formed on the tunnel junction layer 302. The tunnel junction layer 302, which is an AlGaInAs or AlGaAs layer doped with Te or carbon (C), includes a heavily doped n-type layer and a heavily doped p-type layer. The p-type semiconductor layer 303 is p-type doped gallium arsenide, and preferably the dopant is zinc (Zn).

Fourthly, the multiple quantum well layer 304 is disposed on the p-type semiconductor layer 303. The final step to form the epitaxial structure 320 is to dispose the second n-type semiconductor layer 305 on the multiple quantum well layer 304. The material of the second n-type semiconductor layer may be the same as or different from the material of the first n-type semiconductor layer. In this embodiment, the second n-type semiconductor layer 305 and the first n-type semiconductor layer 301 are the same and are gallium arsenide doped with silicon. The second substrate 306 is then bonded onto the second n-type semiconductor layer 305 to complete the formation of the stack structure 35, wherein the second substrate 306 may be a silicon substrate, a sapphire substrate, an aluminum nitride substrate, or a glass substrate. In this embodiment, the second substrate is a silicon substrate.

The following refers to FIG. 4. Continuing the above description of the manufacturing process of the p-side up processing intermediate structure, the stack structure 35 is then flipped upside down. As a result, the top second substrate 306 of the stack structure 35 becomes the bottom layer, and the bottom first substrate 3 of the stack structure 35 becomes the top layer. The first substrate 3 is then removed from the flipped stack structure 35 to complete the process of forming the processing intermediate structure 40.

In general, the energy band difference between a p-type and an n-type semiconductor causes an energy barrier that blocks electrons from flowing from the p-type semiconductor to n-type semiconductor. The addition of the tunnel junction layer between the p-type semiconductor layer and first n-type semiconductor layer lowers the energy barrier at the interface therebetween, so that in forward bias across the processing intermediate structure (which corresponds to a reverse bias locally across the tunnel junction) the different electron and hole energy states on each side of the junction increasingly align, allowing the electrons in the valence band of the p-type semiconductor layer to tunnel to unoccupied sites in the conduction band of the first n-type semiconductor layer. Under reverse bias, electrons tunnel in the opposite direction (in the direction from the p-side to the n-side of the processing intermediate structure), due to electron states on the local n-side of the tunnel junction aligning with hole states on the local p-side of the tunnel junction, thus allowing electrons to tunnel through the tunnel junction from conduction band to valance band. To with, the processing intermediate structure 40 in the embodiment of the present invention includes the first n-type semiconductor layer 301, the tunnel junction layer 302, and the p-type semiconductor layer 303. The component layers of the trilayer structure have the same or extremely similar valence bands; and so the trilayer structure as a whole shows the properties of a p-type semiconductor relative to the second n-type semiconductor layer. Therefore, the trilayer of the first n-type semiconductor layer 301, the tunnel junction layer 302, and the p-type semiconductor layer 303 forms a p-type semiconductor structure 310.

In addition, the disposition of the tunnel junction layer not only solves the problem of increasing voltage but also forms a p-type semiconductor structure 310 by combining the first n-type semiconductor layer 301 and the p-type semiconductor layer 303, and results in the p-type semiconductor structure 310 of the processing intermediate structure 40 being disposed facing upward. The inclusion of the tunnel junction layer therefore implies that the method of the manufacturing process of the p-side up processing intermediate structure of the present invention is able to provide the processing intermediate structure 40 with its p-type semiconductor structure 210 facing upward with the use of only one flipping step, and thereby simplifies the conventional multi-flip procedure of manufacturing a p-side up semiconductor structure, that in the present invention corresponds to the processing intermediate structure

The growth method of the epitaxial structure of the embodiments in the present invention may be by liquid phase epitaxy (LPE), vapor phase epitaxy (VPE) or metal organic chemical vapor deposition (MOCVD).

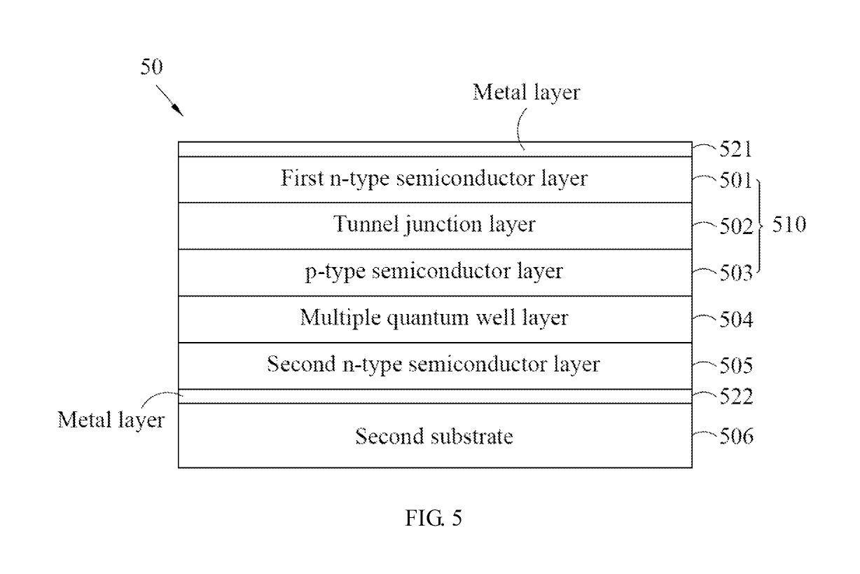

Furthermore, the present invention provides a second embodiment of the p-side up processing intermediate structure, as shown in FIG. 5. From is bottom to top, the processing intermediate structure 50 includes the silicon substrate 506 formed in a way such as that of the second substrate in the first embodiment, the second n-type semiconductor layer 505, the multiple quantum well layer 504, the p-type semiconductor layer 503, the tunnel junction layer 502, and the first n-type semiconductor layer 501. The material of each component of the processing intermediate structure 50 is the same as the material of each component of the processing intermediate structure 40. Moreover, the p-type semiconductor structure 510 is formed by combining the first n-type semiconductor layer 501, the tunnel junction layer 502 and the p-type semiconductor layer 503, wherein the characteristics of the tunneling effect are the same as those aforementioned in the first embodiment. It is thus not necessary to repeat what is written therein. An ohmic contact may be formed between the semiconductor and the metal to introduce electric current into the semiconductor when operating the device in forward bias. As shown in FIG. 5, for the second embodiment this is done by forming multiple metal layers 521 and 522 on the first n-type semiconductor layer 501 and the second n-type semiconductor layer 505 with ohmic contacts between the n-type semiconductor layers and the metals. This facilitates subsequent connection to first and the second electrodes. In this embodiment, metal layers are disposed between the second substrate and the second n-type semiconductor layer and on the first n-type semiconductor layer. The material of the metal layers may be silver (Ag), magnesium (Mg), platinum (Pt), palladium (Pd), gold (Au), Nickel (Ni), neodymium (Nd), iridium (Ir), chromium (Cr), lithium (Li), ytterbium (Yb), germanium gold (GeAu), gold beryllium (BeAu), titanium (Ti), indium tin oxide (ITO), or calcium (Ca). Preferably, the metal layers are formed of germanium gold (GeAu), but the present invention is not limited thereof.

In general, forming an ohmic contact on a p-type semiconductor layer requires an annealing process after forming the metal layer on the p-type semiconductor layer. For commonly used metal materials such as beryllium, gold, or indium tin oxide (ITO), an annealing temperature of 500° C. or higher is required to form an ohmic contact on a p-type semiconductor. However, the metal Indium, which is used in this embodiment, is not able to withstand such high temperatures, thus making it difficult to form an ohmic contact on the p-type semiconductor layer. However, forming an ohmic contact on the p-type semiconductor layer is usually desirable for subsequent use of the processing intermediate structure in specific applications. In the present invention, the processing intermediate structure has the p-type semiconductor structure that includes the second n-type semiconductor layer as the exposed top layer; and so an ohmic contact may be formed on the n-type semiconductor layer with an annealing temperature in the range of 300° C. to 330° C. Therefore, the present invention avoids the difficulty of forming an ohmic contact on a p-type semiconductor layer while still providing the p-type semiconductor structure facing upward.

In summary, by disposing the tunnel junction layer between the n-type semiconductor layer and the p-type semiconductor layer, the trilayer combination forms a structure with the properties of a p-type semiconductor. The upward-facing disposition of the p-type semiconductor structure may be produced with only one flipping step in the manufacturing process, and thereby simplifying the process of manufacturing the processing intermediate structure. Ohmic contacts may be formed in the processing intermediate structure of the present invention by forming metal layers on two n-type semiconductor layers, thereby avoiding the difficulty of forming an ohmic contact on a p-type semiconductor layer. The manufacturing method of the present invention provides the processing intermediate structure with p-side up and includes easily forming the ohmic contacts with metal layers, and thereby simplifies the manufacturing process and reduces the manufacturing costs.

The embodiments herein described are to be interpreted as not limiting the present invention, as the embodiments are merely to illustrate the technical concepts and the features of the present invention in such a way that the invention may be understood and practiced by those of ordinary skill in the art. Numerous modifications, variations and enhancements can be made to the present invention by those skilled in the art without departing from the spirit and scope of the invention set forth in the claims.

What is claimed is:

1. An epitaxial structure having a tunnel junction layer, comprising:
a first substrate;
a first n-type semiconductor layer disposed on the first substrate;
the tunnel junction layer disposed on the first n-type semiconductor layer;
a p-type semiconductor layer disposed on the tunnel junction layer; and
a second n-type semiconductor layer disposed on the p-type semiconductor layer;
wherein the first n-type semiconductor layer, the tunnel junction layer, and
the p-type semiconductor layer jointly form a p-type semiconductor structure.

2. The epitaxial structure of claim 1, further comprising a multiple quantum well layer disposed between the p-type semiconductor structure and the second n-type semiconductor layer.

3. The epitaxial structure of claim 1, wherein the first n-type semiconductor layer, the p-type semiconductor layer, and the second n-type semiconductor layer comprise gallium arsenide, aluminum gallium arsenide, gallium nitride, or gallium phosphide.

4. The epitaxial structure of claim 1, wherein the tunnel junction layer comprises a heavily doped n-type layer and a heavily doped p-type layer including AlGaInAs:Te/C or AlGaAs:Te/C.

5. A method of manufacturing a p-side up processing intermediate structure, comprising the steps of:
providing a first substrate;
forming a first n-type semiconductor layer on the first substrate;
forming a tunnel junction layer on the first n-type semiconductor layer;
forming a p-type semiconductor layer on the tunnel junction layer,
wherein the first n-type semiconductor layer, the p-type semiconductor layer, and the tunnel junction layer jointly form a p-type semiconductor structure;
forming a second n-type semiconductor layer on the p-type semiconductor structure;
bonding a second substrate on the second n-type semiconductor layer to form a stack structure; and
flipping the stack structure upside down followed by removing the first substrate.

6. The method of claim 5, further comprising the step of forming a multiple quantum well layer between the p-type semiconductor structure and the second n-type semiconductor layer.

7. The method of claim 5, further comprising the step of forming an ohmic contact by forming a metal layer between the first substrate and the first n-type semiconductor layer.

8. The method of claim 5, further comprising the step of forming an ohmic contact by forming a metal layer between the second n-type semiconductor layer and the second substrate.

9. The method of claim 5, wherein the first n-type semiconductor layer, the p-type semiconductor layer, and the second n-type semiconductor layer comprise gallium arsenide, aluminum gallium arsenide, gallium nitride, or gallium phosphide.

10. The method of claim 5, wherein the tunnel junction layer comprises a heavily doped n-type layer and a heavily doped p-type layer including AlGaInAs:Te/C or AlGaAs:Te/C.

11. A p-side up processing intermediate structure manufactured by the method of claim 5, comprising:
a second substrate;
a second n-type semiconductor layer disposed on the second substrate; and
a p-type semiconductor structure disposed on the second n-type semiconductor layer, wherein
the p-type semiconductor structure comprises:
a p-type semiconductor layer disposed on the second n-type semiconductor layer;
a first n-type semiconductor layer disposed on the p-type semiconductor layer; and
a tunnel junction layer disposed between the p-type semiconductor layer and the first n-type semiconductor layer.

12. The processing intermediate structure of claim 11, wherein a multiple quantum well layer is disposed between the second n-type semiconductor layer and the p-type semiconductor structure.

13. The processing intermediate structure of claim 11, wherein the first n-type semiconductor layer, the p-type semiconductor layer, and the second n-type semiconductor layer comprise gallium arsenide, aluminum gallium arsenide, gallium nitride, or gallium phosphide.

14. The processing intermediate structure of claim 11, further comprising a metal layer disposed between the second substrate and the second n-type semiconductor layer.

15. The processing intermediate structure of claim 11, further comprising a metal layer disposed on the first n-type semiconductor layer.

16. The processing intermediate structure of claim 11, wherein the tunnel junction layer comprises a heavily doped n-type layer and a heavily doped p-type layer including AlGaInAs:Te/C or AlGaAs:Te/C.
